(19) United States
(12) Patent Application Publication
(10) Pub. No.: US 2011/0037067 A1
(43) Pub. Date: Feb. 17, 2011

(54) ZNO-GROUP SEMICONDUCTOR ELEMENT

(76) Inventors: Ken Nakahara, Kyoto (JP); Masashi Kawasaki, Miyagi (JP); Akira Ohtomo, Miyagi (JP); Atsushi Tsukazaki, Miyagi (JP)

Correspondence Address: RABIN & Berdo, PC, 1101 14TH STREET, NW, SUITE 500, WASHINGTON, DC, 20005, US

(21) Appl. No.: 12/734,772

(22) PCT Filed: Nov. 20, 2008
(86) PCT No.: PCT/JP2008/071108

§ 371 Date: Aug. 6, 2010

(30) Foreign Application Priority Data
Nov. 22, 2007 (JP) 2007-303542

(51) Int. Cl. H01L 29/22

(52) U.S. Cl. 257/43; 257/E29.094

(57) ABSTRACT

Provided is a ZnO-based semiconductor device in which flat ZnO-based semiconductor layers can be grown on a MgZnO substrate having a laminate-side principal surface including a C-plane. With an MgₓZn₁₋ₓO substrate (0≦x<1) with a principal surface including a C-plane, the principal surface is formed so that an angle Φₘ made between a c-axis of substrate's crystal axes and a projection axis obtained by projecting a normal line to the principal surface onto a plane defined by an m-axis and the c-axis of the substrate's crystal axes can be within a range of 0<Φₘ≦3. On the principal surface thus formed, ZnO-based semiconductor layers 2 to 5 are grown epitaxially. A p electrode 8 is formed on the ZnO-based semiconductor layer 5, and an n electrode 9 is formed on the bottom side of the MgₓZn₁₋ₓO substrate 1. In this way, steps are formed on the surface of the MgₓZn₁₋ₓO substrate 1, while being arranged regularly in the m-axis direction. Thereby, a phenomenon known as step bunching can be avoided, and the flatness of the film of each of the semiconductor layers formed on the substrate 1 can be improved.

### TECHNICAL FIELD

The invention relates to a ZnO-based semiconductor device using a ZnO-based semiconductor such as ZnO and MgZnO.

### BACKGROUND ART

ZnO-based semiconductors have been attracting much attention as a material that is superior in versatility to such nitride semiconductors containing nitrogen as GaN, AlGaN, InGaN, InGaAlN, and GaPN.

Being a kind of wide-gap semiconductors, ZnO-based semiconductors have a remarkably large exciton binding energy, are capable of stably existing at room temperature, and are capable of radiating photons with excellent monochromaticity. For these reasons and others, ZnO-based semiconductors have been put into various practical uses in ultraviolet LEDs used as light sources for illumination or backlight, high-speed electron devices, surface-acoustic-wave devices, and the like.

ZnO-based semiconductors, however, have a well-known problem. Defects are caused in ZnO-based semiconductor crystals by such reasons as oxygen vacancies and interstitial zinc molecules. The crystal defects generate non-contributing electrons in the crystal, which cause the ZnO-based semiconductor to have the n type conductivity under ordinary conditions. Accordingly, in order to convert the conductivity of a ZnO-based semiconductor into p type, it is necessary to decrease the concentration of the remaining electrons. Consequently, it is difficult to dope acceptors into the ZnO-based semiconductor. As a result, if a semiconductor device is formed with a ZnO-based semiconductor layer, it has been difficult to form a p type ZnO with excellent reproducibility.

However, in recent years, p type ZnO has become obtainable with better reproducibility, and moreover, light emission from p type ZnO has been observed. Techniques concerning such p type ZnO have been disclosed. For example, Non-Patent Document 1 discloses a technique in which p type ZnO is obtained. To obtain a semiconductor device using a ZnO-based semiconductor, a ScAlMgO₄ (SCAM) substrate is used as a growth substrate and −C-plane ZnO is grown on the C-plane of the SCAM substrate. The above-mentioned −C-plane is also known as O (oxygen) polar plane. In the wurtzite crystal structure, which is the crystal structure of ZnO crystal, there is no symmetry in the c-axis directions. The c-axis has two directions that are independent of each other, namely the +c direction and the −c direction. In the +c direction, Zn is situated at the uppermost plane of the crystal, so that the +c direction is also called Zn-polarity. In the −c direction, on the other hand, O is situated at the uppermost plane, so that the −c direction is also called O-polarity.

The −C-plane ZnO may be grown on a sapphire substrate, which is quite frequently used as a substrate for the growth of ZnO-crystal. As the inventors' Non-Patent Document 2 shows, in the crystal growth of −C-plane ZnO-based semiconductors, the efficiency of the doping of nitrogen, which is a p type dopant, depends largely on the growth temperature. Accordingly, when nitrogen is doped, it is necessary to lower the temperature of the substrate. Lowering the temperature of the substrate, however, impairs the crystallinity and forms carrier-compensation centers that compensate the acceptors. The forming of such carrier-compensation centers prevents the activation of nitrogen, so that the formation of the p type ZnO-based semiconductor layer per se is made very difficult.

In this regard, Non-patent Document 1 describes a method of avoiding the problem. The method takes advantage of the fact that the nitrogen-doping efficiency depends on the temperature. To be more specific, according to the method, a p type ZnO-based semiconductor layer with a high concentration of carriers is formed by a temperature modulation in which the growth temperature is repeatedly raised from 400° C. up to 1000° C. and then lowered from 1000° C. down to 400° C. This method, however, has its own drawbacks. The incessantly repeated heating-up and cooling-down makes the manufacturing apparatus expand and shrink repeatedly, which means a heavier load on the manufacturing apparatus. In addition, the manufacturing apparatus has to be larger in size, and the maintenance work for the manufacturing apparatus needs to be done in shorter cycles. Moreover, the use of laser apparatus as the source of heating makes the apparatus inappropriate for the heating of a larger area. The inappropriateness, in turn, poses difficulty in carrying out multiple-wafer growth, which is necessary if a reduction in the device manufacturing cost is to be pursued.

The inventors have already proposed a method of solving this problem (see Patent Document 1). According to the method, a p type ZnO-based semiconductor with a high concentration of carriers is formed by growing a +C-plane ZnO-based semiconductor layer. Patent Document 1 is based on the inventors' discovery of the fact that, in the case of +C-plane ZnO, the doping of nitrogen does not depend on the temperature of the substrate. The non-dependence of the nitrogen doping on the growth temperature was discovered by: firstly growing a +C-plane GaN film, which serves as an underlying layer, on the C-plane of a sapphire substrate to obtain a +c-axis-oriented GaN film; and then forming a +c-axis oriented ZnO-based semiconductor layer on this +c-axis-oriented GaN film so that the ZnO-based semiconductor layer thus formed can have the same polarity as that of the +c-axis-oriented GaN film. Accordingly, nitrogen can be doped without lowering the temperature of the substrate. Consequently, the formation of carrier-compensation centers can be avoided, which makes it possible to manufacture a p type ZnO-based semiconductor with a high concentration of carriers.

Patent Document 1: JP-A2004-304166

Non-Patent Document 1: Nature Materials, vol. 4 (2005), p. 42

Non-Patent Document 2: Journal of Crystal Growth, 237-239 (2002), p. 503

### DISCLOSURE OF THE INVENTION

### Problems to be Solved by the Invention

As has been described above by referring to the conventional technique, a p type ZnO-based semiconductor with a high concentration of carriers can be formed by forming a +c-axis oriented ZnO-based semiconductor layer by use of a +C-plane GaN of a growth substrate. This method, however, is characterized by preventing the surface of the +C-plane GaN film from being oxidized. So, in the case of ZnO, which is an oxide, it is difficult to secure reproducibility of a satisfactory level. In addition, though it is possible to use a +C-plane ZnO substrate as a growth substrate, the +C-plane ZnO substrate is more thermally unstable, and more likely to lose the flatness, than the −C-plane ZnO substrate. The use of a +C-plane ZnO substrate as a substrate upon which crystal is grown brings about a phenomenon known as the “step bunching.” Consequently, flat portions of the plane do not have a uniform width. That is, the widths of the flat portions differ from one another.

FIG. 23(a) shows an image of the surface of the −C-plane of a growth substrate whereas FIG. 23(b) shows an image of the surface of +C-plane of a growth substrate. These growth substrates are subjected to an annealing process at 100° C. in the atmosphere before the surface of the corresponding plane of each substrate is scanned using an atomic force microscope (AFM) with a view field of a 5-μm square. The crystal shown in FIG. 23(a) has a neatly-formed surface. In contrast, the surface shown in FIG. 23(b) has step bunching and the widths of the steps as well as the edges of the steps are formed in a disorderly fashion. In short, the state of the surface shown in FIG. 23(b) is bad. If, for example, a ZnO-based compound is grown epitaxially on the surface shown in FIG. 23(b), the ZnO-based compound would be a film having asperities scattered all over the surface, such as one shown in FIG. 24, and its flatness would be extremely poor.

As described above, it is difficult to grow a flat film on the +C-plane of a growth substrate. Accordingly, there has been the problem of eventually reducing the quantum effect of the device and affecting the switching speed of the device.

The present invention has been made to address the problems described above, and aims to provide a ZnO-based semiconductor device in which a flat ZnO-based semiconductor layer can be formed on a MgZnO substrate with a principal surface on the laminate side having a C-plane.

### Means for Solving Problems

In order to achieve the above-described object, an invention according to claim 1 is a ZnO-based semiconductor device comprising: a MgₓZn₁₋ₓO substrate (0≦x<1) having a principal surface including a C-plane; and a ZnO-based semiconductor layer formed on the principal surface, the ZnO-based semiconductor device characterized in that, in the MgₓZn₁₋ₓO substrate, a projection axis obtained by projecting a normal line to the principal surface onto a plane defined by an m-axis and a c-axis of substrate's crystal axes, forms an angle of Φₘ degrees with the c-axis, and that the Φₘ satisfies a condition of 0<Φₘ≦3.

Further, an invention according to claim 2 is the ZnO-based semiconductor device according to claim 1 characterized in that, regarding the Φₘ, the condition of 0<Φₘ≦3 is replaced by a condition of 0.1≦Φₘ≦1.5.

Further, an invention according to claim 3 is a ZnO-based semiconductor device according to any one of claim 1 and claim 2 characterized in that the C-plane is a +C-plane.

Further, an invention according to claim 5 is the ZnO-based semiconductor device according to any one of claim 1 to claim 3 characterized in that a projection axis obtained by projecting the normal line to the principal surface onto a plane defined by an a-axis and the c-axis of the substrate's crystal axes forms an angle of Φₐ degrees with the c-axis, and that the Φₐ satisfies a condition of

70≦{90−(180/π)arctan(tan(πΦₐ/180)/tan(Φₘ/180))}≦110.

Further, an invention according to claim 5 is a Zn—O semiconductor device comprising: a MgₓZn₁₋ₓO substrate (0≦x<1) having a principal surface including a C-plane; and a ZnO-based semiconductor layer formed on the principal surface, the Zn—O semiconductor device characterized in that, in the MgₓZn₁₋ₓO substrate, a normal line to the principal surface tilts from a c-axis only towards an m-axis, and that a tilting angle of the normal line is larger than 0 degree and is not larger than 3 degrees.

Further, an invention according to claim 6 is the ZnO-based semiconductor device according to claim 5 characterized in that the tilting angle is not smaller than 0.1 degrees and is not larger than 1.5 degrees.

### Effect of the Invention

According to the ZnO-based semiconductor device of the present invention, the projection axis formed by projecting the normal line to the principal surface of the MgₓZn₁₋ₓO substrate (0≦x<1) onto the plane defined by the m-axis and the c-axis of the axes of the crystal of the substrate makes an angle of Φₘ degrees with the c-axis, and the value of Φₘ is within a range of 0<Φₘ≦3. Thereby, steps regularly arranged in the m-axis directions can be formed on the laminate-side surface of the MgₓZn₁₋ₓO substrate. Accordingly, the phenomenon known as step bunching can be avoided, and the flatness of the film of each of the ZnO semiconductor layers formed on the MgₓZn₁₋ₓO substrate can be improved.

In addition, in the case where the projection axis formed by projecting the normal line to the principal surface of the MgₓZn₁₋ₓO substrate onto the plane defined by the a-axis and the c-axis of the axes of the crystal of the substrate makes an angle of Φₐ degrees with the c-axis, steps on the growth plane of the MgZnO substrate can be arranged in the m-axis directions by setting the value of Φₐ within a range of 70≦{90−(180/π) arctan (tan(πΦₐ/180/tan(πΦₘ/180)≦110. Accordingly, the flatness of the film formed on the principal surface can be improved.

### BRIEF DESCRIPTION OF THE DRAWINGS

FIG. 1 is a diagram illustrating an exemplar cross-sectional structure of a ZnO-based semiconductor device of the invention.

FIG. 2 is a schematic diagram illustrating the crystal structure of a ZnO-based compound.

FIG. 3 is a diagram illustrating the relationship among the normal line to the principal surface of the substrate, and the axes of the crystal of the substrate, namely the c-axis, the m-axis, and the a-axis.

FIG. 4 shows diagrams illustrating the relationships that the tilting state of the normal line to the principal surface of a MgₓZn₁₋ₓO substrate and the state of the step edges respectively have with the m-axis.

FIG. 5 shows diagrams illustrating the surface of the MgₓZn₁₋ₓO substrate in the case where the normal line to the principal surface of the substrate has an off-angle only in an m-axis direction.

FIG. 6 shows diagrams illustrating the surface of the MgₓZn₁₋ₓO substrate in the case where the normal line to the principal surface of the substrate has an off-angle in the m-axis direction as well as in the a-axis direction.

FIG. 7 shows diagrams illustrating how the state of the surface of the MgₓZn₁₋ₓO substrate changes depending on the off-angle of the normal line to the principal surface of the substrate in the m-axis direction and in the a-axis direction.

FIG. 8 is a diagram illustrating the surface of a film formed on a MgₓZn₁₋ₓO substrate in which the normal line to the principal surface of the substrate has an off-angle in the m-axis direction.

FIG. 9 is a diagram illustrating the surface of a film formed on a MgₓZn₁₋ₓO substrate in which the normal line to the principal surface of the substrate has an off-angle in the m-axis direction.

FIG. 10 is a diagram illustrating the surface of a film formed on a MgₓZn₁₋ₓO substrate in which the normal line to the principal surface of the substrate has an off-angle in the m-axis direction.

FIG. 11 shows diagrams each illustrating the surface of a film formed on a MgₓZn₁₋ₓO substrate in which the normal line to the principal surface of the substrate has an off-angle of 0.1 degrees in the m-axis direction.

FIG. 12 shows diagrams each illustrating the surface of a film formed on a MgₓZn₁₋ₓO substrate in which the normal line to the principal surface of the substrate has an off-angle of 0.5 degrees in the m-axis direction.

FIG. 13 shows diagrams each illustrating the surface of a film formed on a MgₓZn₁₋ₓO substrate in which the normal line to the principal surface of the substrate has an off-angle of 1.5 degrees in the m-axis direction.

FIG. 14 is a chart illustrating a PL-spectrum profile of a ZnO film for different off-angles between the normal line to the principal surface of the substrate and the m-axis.

FIG. 15 is a chart illustrating the relationship between the PL-integrated intensity and the ratio of the band-end luminescence peak/the deeper level luminescence peak, for different off-angles between the normal line to the principal surface of the substrate and the m-axis.

FIG. 16 is a diagram showing the thermal stability of the M-plane when the A-plane and the M-plane are compared.

FIG. 17 is a diagram showing a chemical stability of the M-plane.

FIG. 18 is a diagram showing a chemical stability of the M-plane.

FIG. 19 is a diagram showing a chemical stability of the M-plane.

FIG. 20 is a diagram illustrating a kink position on a wafer in the course of crystal growth.

FIG. 21 is a diagram illustrating the state of the surfaces of a MgₓZn₁₋ₓO substrate in which the off-angle made by the normal line to the principal surface of the substrate in the a-axis direction is different.

FIG. 22 is a diagram illustrating an exemplar cross-sectional structure of a transistor formed by the technique of the present invention.

FIG. 23 is a diagram illustrating the surfaces of a film formed respectively on the −C-plane of a growth substrate and formed on the +C-plane of a growth substrate.

FIG. 24 is a diagram illustrating the surface after further forming semiconductor layers on the surface shown in Part (b) of FIG. 23.

### DESCRIPTION OF REFERENCE NUMERALS

1 MgₓZnO substrate
2 n type layer
3 active layer
4 p type layer
5 p type contact layer
8 p electrode
9 n electrode

### BEST MODE FOR CARRYING OUT THE INVENTION

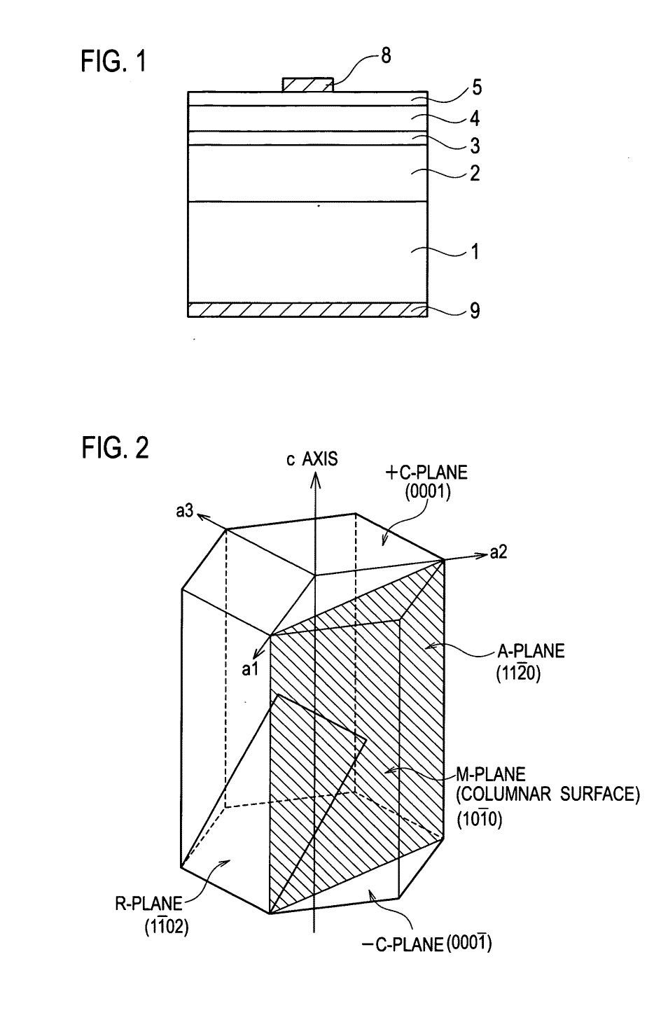

An embodiment of the present invention will be described below by referring to the drawings. FIG. 1 shows a cross-sectional structure of a ZnO-based semiconductor device of the present invention.

FIG. 1 shows a cross-sectional structure of a light-emitting diode (LED), which is an embodiment of the ZnO-based semiconductor device of the invention. A MgₓZn₁₋ₓO substrate 1 (0≦x<1; preferably, 0≦x≦0.5) has a principal surface of the substrate including +C-plane (0001), and the normal line to the principal surface tilts from the c-axis. ZnO-based semiconductor layers 2 to 5 are grown epitaxially on the MgₓZn₁₋ₓO substrate 1. Here, 2 represents an n type layer, 3 represents an activation layer, 4 represents a p type layer, and 5 represents a p type contact layer. Then, a p electrode 8 is formed on the p type contact layer 5, and an n electrode 9 is formed on the bottom side of the MgₓZn₁₋ₓO substrate 1. Each ZnO-based semiconductor layer is made of either ZnO or a compound containing ZnO. The above-described ZnO-based semiconductor device is entirely made of either ZnO or a compound containing ZnO, except for the electrodes 8 and 9.

Now, a conceptual diagram of the crystal structure of such a ZnO-based compound as the above-mentioned MgₓZn₁₋ₓO is shown in FIG. 2. Like GaN, a ZnO-based compound has a hexagonal crystal structure known as wurtzite. Planes and axes such as the C-plane and the a-axis can be expressed also with the so-called Miller's indices. For example, the C-plane is expressed as the (0001) plane. In FIG. 2, the plane marked with oblique lines is the A-plane, which is the (11-20) plane. The M-plane, which is the (10-10) plane, forms a columnar surface of the hexagonal crystal structure. For example, since the crystal has a symmetrical structure, such terms as the {11-20} plane and the {10-10} plane are used as generic terms representing also planes that are equivalent, respectively, to the (11-20) plane and the (10-10) plane. Note also that the a-axis represents the direction that is perpendicular to the A-plane, the m-axis represents the direction that is perpendicular to the M-plane and the c-axis represents the direction that is perpendicular to the C-plane.

The MgₓZn₁₋ₓO substrate 1, which serves as the substrate for the crystal growth, may be made of ZnO, that is, x=0. Alternatively, the MgₓZn₁₋ₓO substrate 1 may be a MgZnO substrate with Mg mixed in the crystal. In this case, however, if the Mg content exceeds 50 wt %, the NaCl-type crystal of MgO becomes less conformable to the ZnO-based compound with a hexagonal crystal structure. Therefore, phase separation is more likely to be caused. So, a MgZnO with a Mg content of 50 wt % or higher is nor preferable.

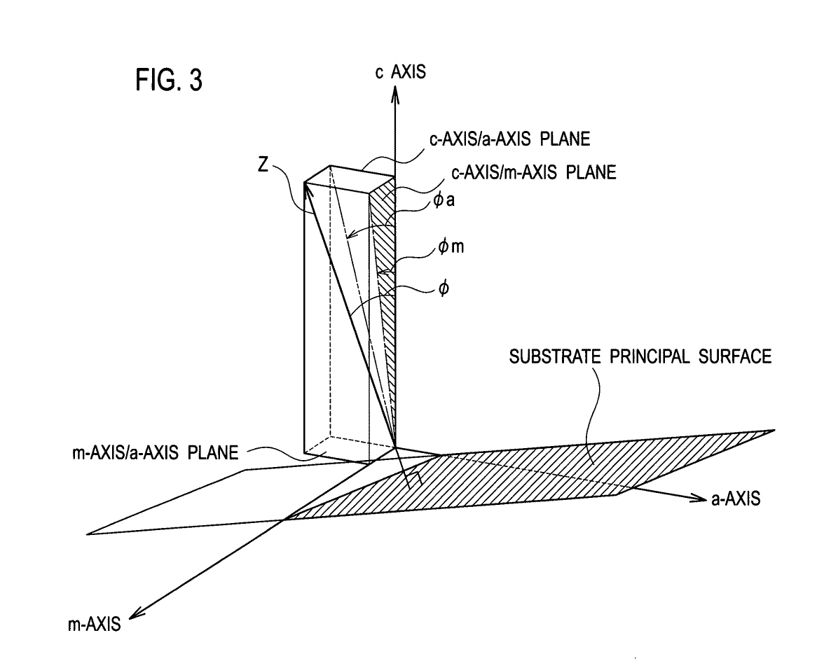

Further, as FIG. 3 shows, the MgₓZn₁₋ₓO substrate 1 is polished so that the normal line to a substrate's principal surface including the +C plane can tilt from the c-axis and that the normal line to the substrate's principal surface can tilt from the c-axis towards, at least, the m-axis. FIG. 3 shows the case where: the normal line Z to the substrate's principal surface tilts from the c-axis of the substrate's crystal axes by an angle of Φ degrees; a projection axis (shadow axis) is formed by projecting (forming the shadow of) the normal line Z onto the c-axis/m-axis plane in the Cartesian coordinate system defined by the c-axis, the m-axis, and the a-axis, which are the substrate's crystal axes, and the projection axis thus formed tilts from the c-axis towards the m-axis by an angle of Φₘ degrees; and a projection axis (shadow axis) is formed by projecting the normal line Z onto the c-axis/a-axis plane, and the projection axis thus formed tilts from the c-axis towards the a-axis by an angle of Φₐ degrees.

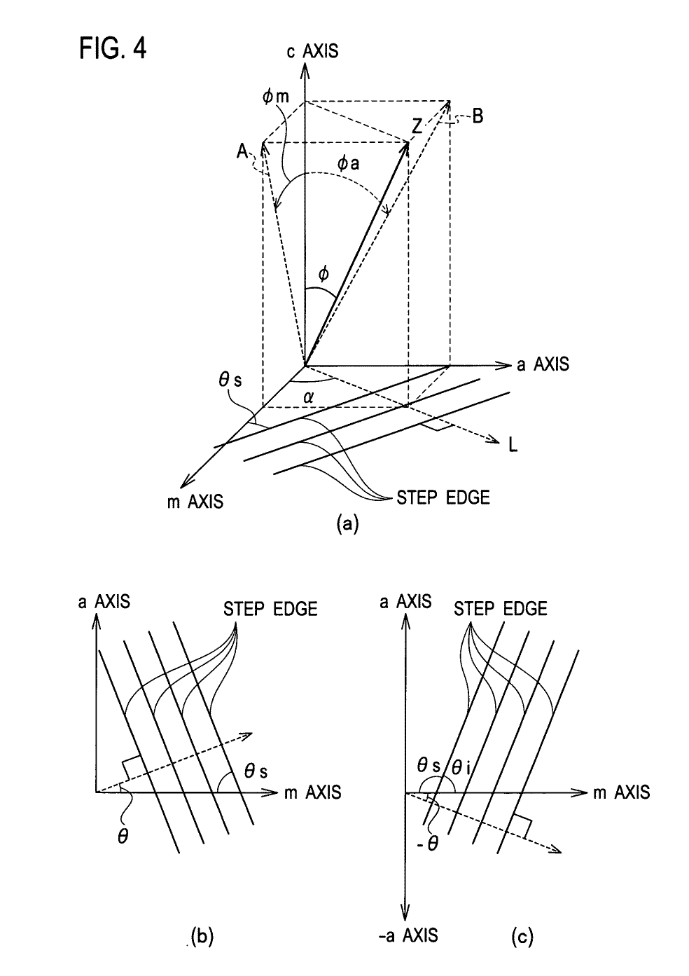

The state where the normal line Z to the substrate's principal surface tilts as in the case shown in FIG. 3 is shown in a more easily-comprehensible manner by FIG. 4(a). FIG. 4(a) shows the relationship between the normal line Z and the Cartesian coordinate system defined by the c-axis, the m-axis, and the a-axis. FIG. 4(a) differs from FIG. 3 only in the direction in which the normal line Z to the substrate's principal surface tilts. The symbols Φ, Φₘ, and Φₐ in FIG. 4(a) represent the same as in FIG. 3. FIG. 4(a) shows a projection axis A and a projection axis B. The projection axis A is obtained by projecting the normal line Z to the substrate's principal surface onto the c-axis/m-axis plane in the Cartesian coordinate system defined by the c-axis, the m-axis, and the a-axis, whereas the projection axis B is obtained by projecting the normal line Z to the substrate's principal surface onto the c-axis/a-axis plane.

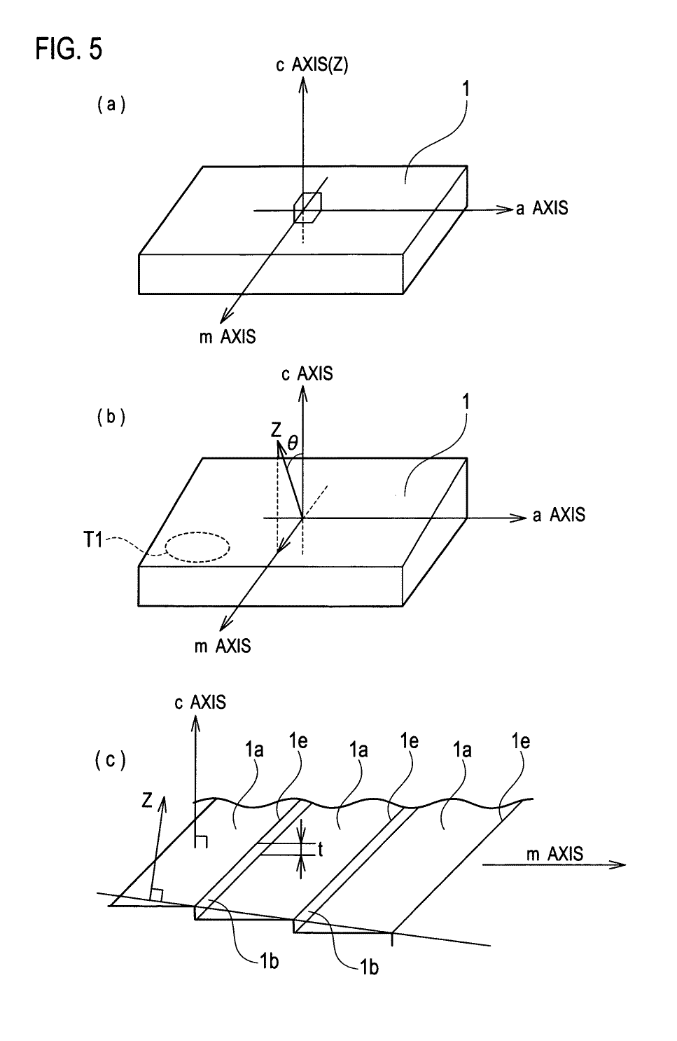

Now, description is given of the reason why the normal line to the principal surface of the substrate is made to tilt from the c-axis towards the m-axis. FIG. 5(a) is a schematic diagram showing a case where the normal line Z to the substrate's principal surface including the +C-plane coincides with the +c-axis, that is, where the normal line Z tilts neither towards the a-axis nor towards the m-axis. In this case, the normal line Z that extends in the perpendicular direction with respect to the principal surface of the substrate 1 coincides with the +c-axis direction, and the a-axis, the m-axis, and the c-axis orthogonally intersect with each other.

In a bulk crystal, the direction of the normal-line to the principal surface of the wafer does not coincide with the c-axis direction as in the case shown in FIG. 5(a) unless a cleavage plane that the crystal has is used for the purpose. In addition, if a C-plane just substrate is the only option to be used, the productivity of wafers becomes lower. In practice, the normal line Z to the wafer's principal surface tilts from the c-axis and has an off-angle. Suppose, for example, a case like the one shown in FIG. 5(b), where the normal line Z to the principal surface exists within the c-axis/m-axis plane and the normal line Z tilts from the c-axis only towards the m-axis by an angle of θ degrees. In this case, as shown in FIG. 5(c), which is an enlarged diagram illustrating a portion (for example, an area T1) of the surface of the substrate 1, terrace faces 1a which are flat and step faces 1b are formed. The step faces 1b, which regularly appear at equal intervals, are each formed in a portion where a difference in level is formed due to the fact that the normal line Z tilts.

Here, each of the terrace faces 1a corresponds to the C-plane (0001), whereas each of the step faces 1b corresponds to the M-plane (10-10). As shown in the drawing, the step faces 1b are configured to align regularly in the m-axis direction at uniform intervals, each of which is equal to the width of each of the terrace faces 1a. As a result, the c-axis that is perpendicular to the terrace faces 1a and the normal line Z to the substrate's principal surface form an off-angle of θ degrees.

The state shown in FIG. 5(c) corresponds to the case where θₓ=90 degrees in FIG. 4. Note that, the step edges shown in FIG. 4 are obtained by projecting the level-difference portions formed by the step faces 1b onto the a-axis/m-axis plane. If, as in the above-described case, the step faces are formed so as to be planes equivalent to the M-plane, the ZnO-based semiconductor layers whose crystals are grown on the principal surface can be formed as flat films. Level-difference portions are formed on the principal surface due to the step faces 1b, but atoms that comes flying to the level-difference portions can be bonded to the two faces: the corresponding terrace face 1a and the corresponding step face 1b. So, such atoms can be bonded more strongly than the atoms that come flying to terrace faces 1a. Consequently, the flying atoms can be trapped in a stable manner.

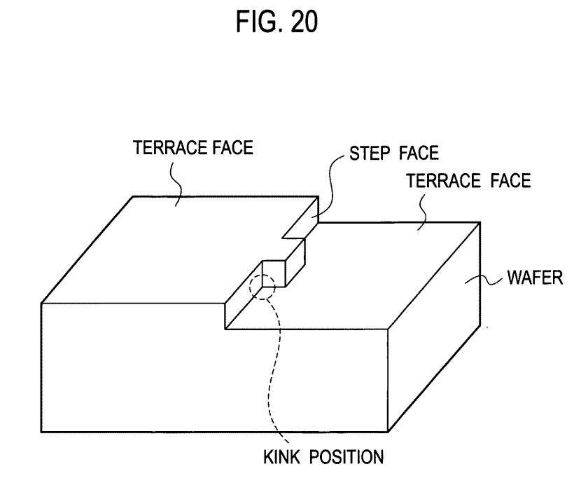

The flying atoms diffuse within the terrace in the process of surface diffusion. The flying atoms are used for a stable growth by a lateral growth in which the atoms are trapped at the level-difference portions where the bonding force is strong or at a kink positions formed at the level-difference portion (refer to FIG. 20) and are then incorporated into the crystal. As has been described thus far, if ZnO-based semiconductor layers are formed on a substrate in which the normal line to the substrate's principal surface tilts at least towards the m-axis, a crystal growth occurs around the step faces 1b; thus, flat films of the respective ZnO-based semiconductor layers can be formed.

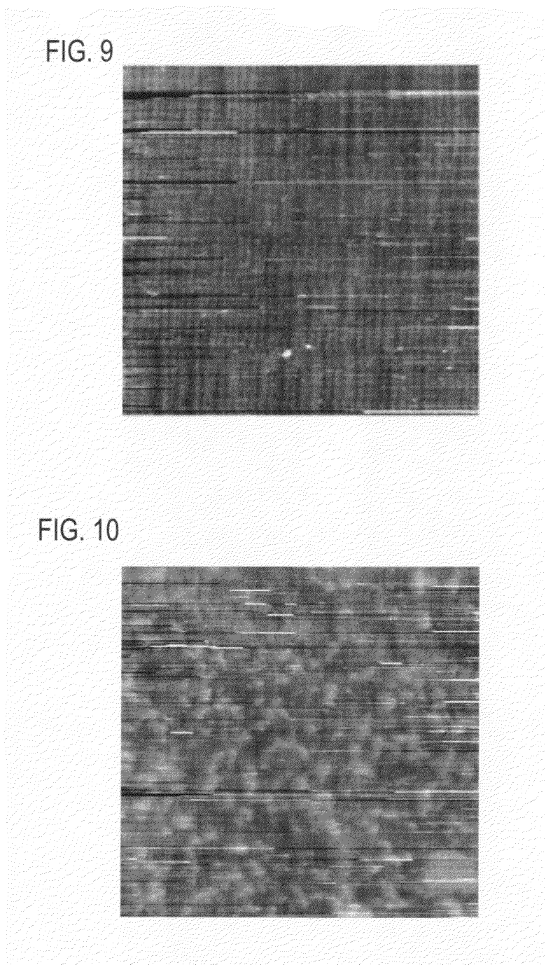

If, however, the tilting angle θ shown in FIG. 5(b) is made too large, the level difference at each step face lb becomes too large to grow a crystal in a flat manner. FIGS. 9 and 10 show how the flatness of the grown film changes depending on the tilting angle towards the m-axis. FIG. 9 shows a case where the tilting angle θ is set to be 1.5 degrees and a ZnO-based semiconductor is grown on a principal surface of a MgₓZn₁₋ₓO substrate that has this off-angle. FIG. 10, on the other hand, shows a case where the off-angle 9 is set to be 3.5 degrees and a ZnO-based semiconductor is grown on a principal surface of a MgₓZn₁₋ₓO substrate that has this off-angle. Each of FIGS. 9 and 10 are an image obtained by scanning the grown crystal by use of an AFM with a view field of 1-μm square. To be more specific, an undoped ZnO film is formed on a ZnO substrate, and then the surface of the undoped ZnO film is scanned to get the image.

The image of FIG. 9 shows the steps with uniform widths and a finely-formed film. In contrast, the image of FIG. 10 shows asperities scattered all over the image, indicating that the flatness is lost. Accordingly, a preferable off-angle is larger than 0 degree but is not larger than 3 degrees (0<θ≦3). In addition, a preferable tilting angle Φₘ shown in FIG. 4 is within the similar range. Specifically, a preferable tilting angle Φₘ is larger than 0 degree but is not larger than 3 degrees (0<Φₘ≦3).

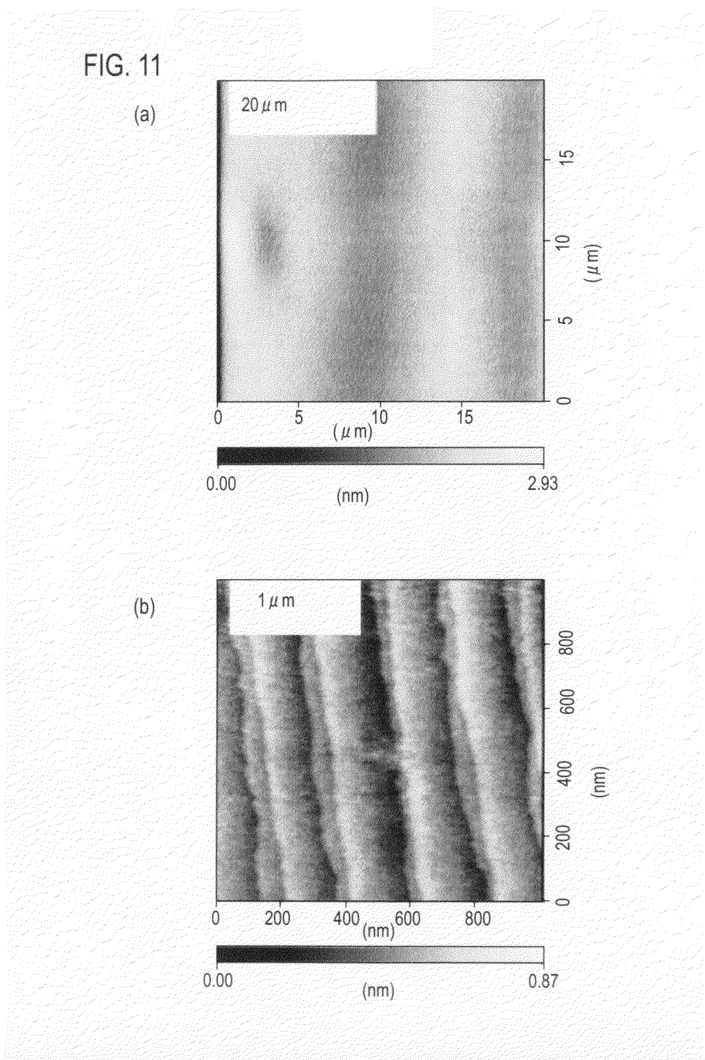

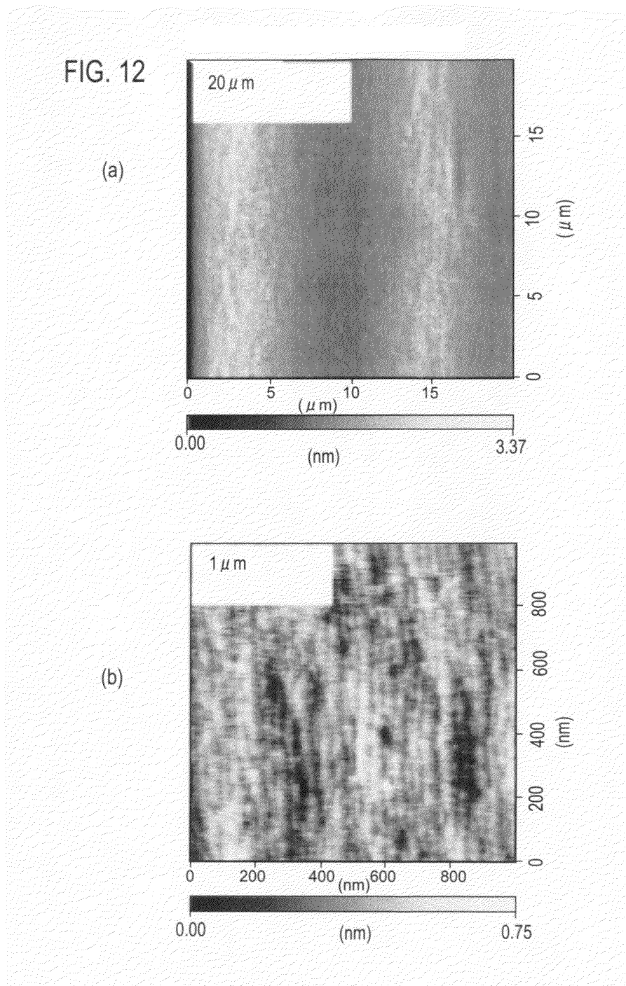

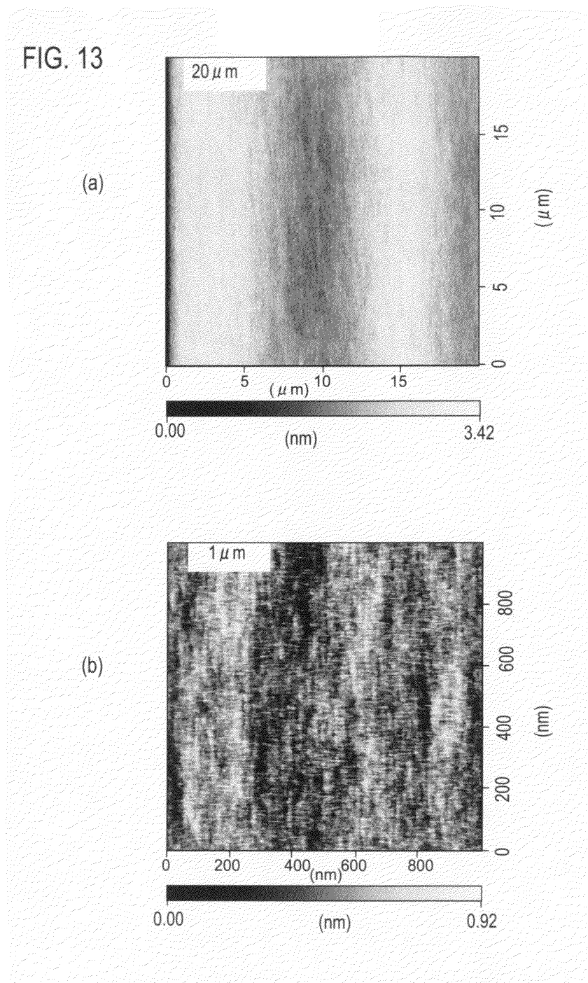

Subsequently, by setting the off-angle θ at more detailed levels, undoped ZnO films are formed respectively on ZnO substrates in a similar manner to the above-described one. The surface of each of the undoped ZnO films thus formed is observed with an AFM. FIGS. 11 to 13 show the images of the surfaces. Specifically, FIG. 11 shows a case where the off-angle θ of the principal surface of the ZnO substrate is 0.1 degrees, FIG. 12 shows a case where the off-angle θ of the principal surface of the ZnO substrate is 0.5 degrees, and FIG. 13 shows a case where the off-angle θ of the principal surface of the ZnO substrate is 1.1 degrees. In each of the cases shown in FIGS. 11 to 13, the crystal of the undoped ZnO film is grown on the ZnO substrate that is kept at a temperature of 870° C., and the image of the surface of the undoped ZnO film is taken using an AFM. For all FIGS. 11 to 13, (a) is an image taken with a view field of 20-μm square whereas (b) is an image taken with a view field of 1-μm square

The images show that with an off-angle θ within a range from 0.1 degrees to 1.5 degrees, the steps formed on each undoped ZnO film have uniform widths and a flat film is formed. Nevertheless, if the off-angle θ is as small as 0.1 degrees approximately as in the case shown in FIG. 11, the widths of the steps are not so neatly ordered and begin to become in disorder. This is assumed because it is becoming impossible to keep the single-molecular step of the undoped ZnO film

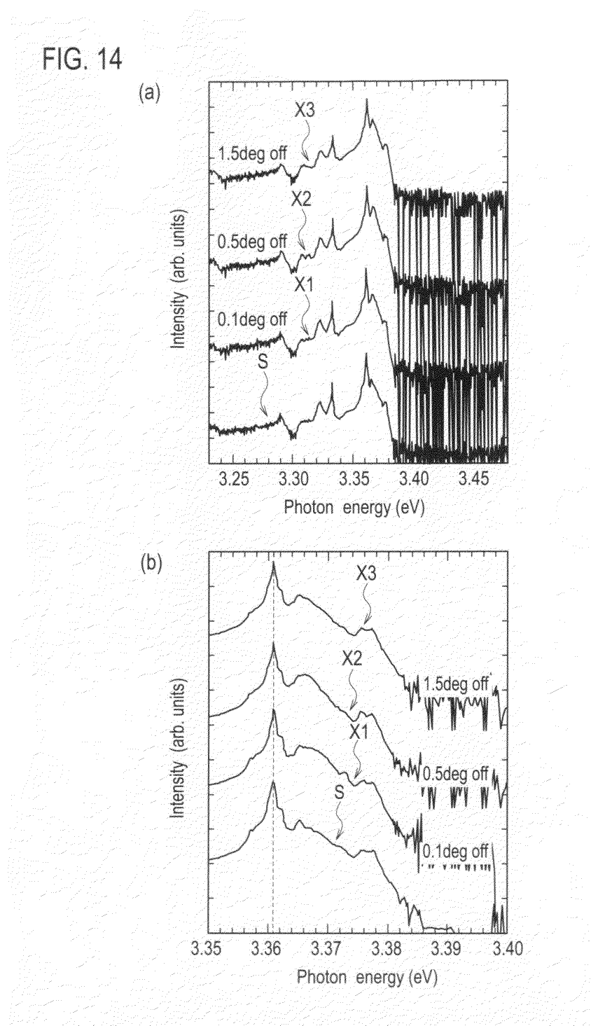

Now, the undoped ZnO film examined in the cases shown in FIGS. 11 to 13 are subjected to a photoluminescence (PL) measurement. FIG. 14 shows the spectrum profiles obtained as a result of this PL measurement. The PL measurement is conducted at an absolute temperature of 12 K (Kelvin) and with a diffraction grating with 2400 rulings per millimeter. The horizontal axis of FIG. 14 represents the luminescence energy (in eV). The vertical axis represents the PL intensity, which is expressed using an arbitrary unit (in logarithmic scale) that is usually used at PL measurements. FIG. 14(b) is an enlarged diagram showing the spectrum profile of the area demarcated by a luminescence-energy range from 3.35 eV to 3.40 eV. In each of FIGS. 14(a) and 14(b), X1 represents a case with an off-angle θ of 0.1 degrees, X2 represents a case with an off-angle θ of 0.5 degrees, and X3 represents a case with an off-angle θ of 1.5 degrees. In addition, S represents a case where the off-angle θ is 0.5 degrees and the undoped ZnO film that is formed on the ZnO substrate is grown at a temperature of 800° C. FIG. 14 shows that there is no observable difference in the effect caused by the difference in the off-angle θ as long as the off-angle θ is within a range from 0.1 degrees to 1.5 degrees

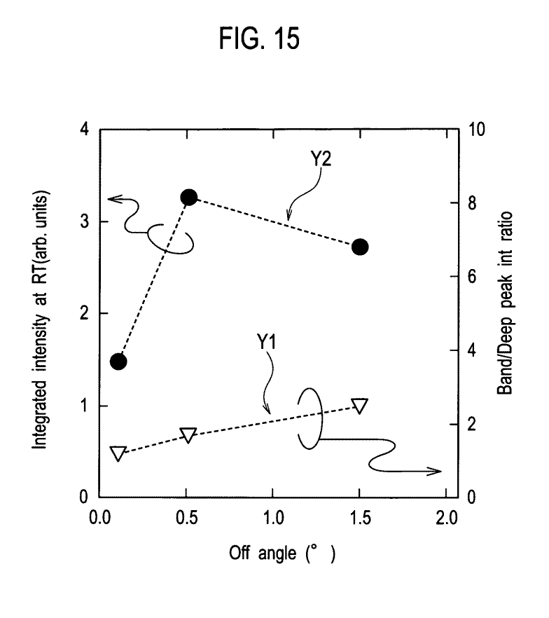

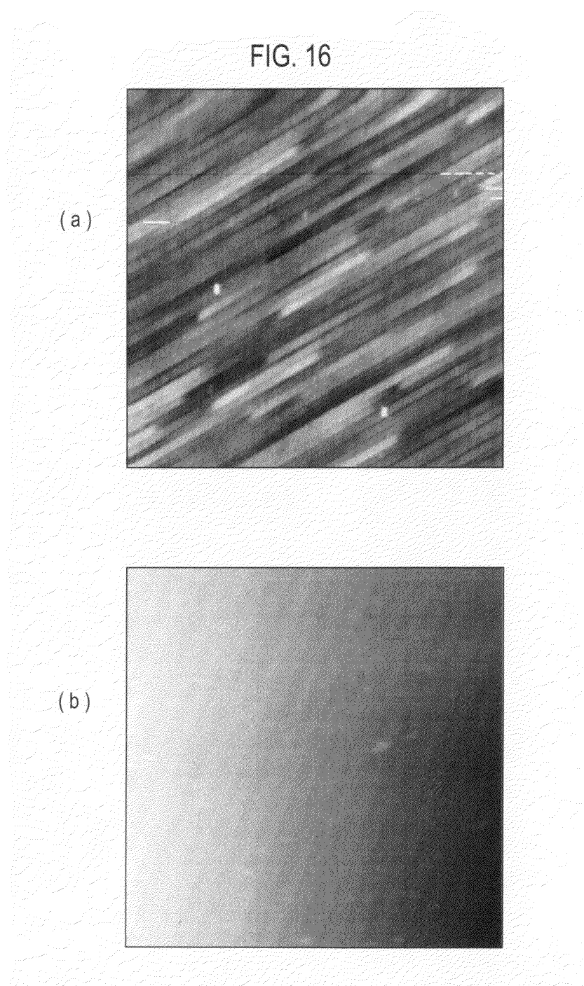

Similar undoped ZnO films to those used in the cases of FIGS. 11 to 13 and FIG. 14 are subjected to a PL measurement at room temperature with the off-angles of the normal line to the principal surface of the ZnO substrate being set at 0.1 degrees, 0.5 degrees, and 1.5 degrees. Spectrum profiles such as ones shown in FIG. 14 are calculated. Then, integral values obtained by integrating the spectrums for a range from a 340-nm luminescence wavelength to a 440-nm luminescence wavelength are plotted. In each of the spectrum profiles, there appear a band-end luminescence and a deep-level luminescence. The ratio of the peak of the band-end luminescence to the peak of the deep-level luminescence is also calculated and is plotted in FIG. 15. In FIG. 15, the horizontal axis represents the off-angle θ, the vertical axis on the left-hand side represents the PL integrated intensity at room temperature (Integrated intensity at RT) expressed in an arbitrary unit, and the vertical axis on the right-hand side represents the ratio of the band-end luminescence peak to the deep-level luminescence peak (Band/Deep peak int ratio).

Further, Y2 indicated by black circles represents the PL integrated intensities of the undoped ZnO films with off-angles of 0.1 degrees, 0.5 degrees, and 1.5 degrees, respectively, and Y1 indicated by white triangles (Δ)) represents the ratios of the band-end luminescence peak to the deep-level luminescence peak at respective off-angles θ. As FIG. 15 shows, both the PL integrated intensity and the ratio of the band-end luminescence peak to the deep-level luminescence peak are slightly lower in the case of the off-angle θ being 0.1 degrees, but there can be observed no noticeable difference in the effect in the cases of the other two off-angles.

Accordingly, a more preferable off-angle θ is within a range of 0.1 degrees≦0≦1.5 degrees. In addition, the same applies to the tilting angle Φₘ shown in FIG. 4. Therefore, a more preferable tilting angle θₘ is within a range of 0.1 degrees≦Φₘ≦1.5 degrees.

As has been described thus far, what is preferable is that: the normal line Z to the principal surface exists within the c-axis/m-axis plane; the normal line Z tilts from the c-axis only towards the m-axis; and the tilting angle of the normal line Z is set within the above-mentioned range. In practice, however, it is difficult to cut out only the substrate with the normal line Z to the principal surface tilting only towards the m-axis. So, as a technique for production, it is necessary to allow the tilting of the normal line Z also towards the a-axis and to set the allowable range of the tilting in this direction. For example, an allowable substrate may have a principal surface fabricated as the one shown in FIG. 4. Specifically, in the substrate, the normal line Z to the substrate's principal surface tilts from the c-axis of the substrate's crystal axes by an angle of Φ degrees; the projection axis formed by projecting the normal line Z onto the c-axis/m-axis plane in the Cartesian coordinate system defined by the c-axis, the m-axis, and the a-axis, which are the substrate's crystal axes, tilts from the c-axis towards the m-axis by an angle of Φₘ degrees; and the projection axis formed by projecting the normal line Z onto the c-axis/a-axis plane tilts from the c-axis towards the a-axis by an angle of Φₐ degrees. In this case, however, the angle θₛ made between the step edge of each step face and the m-axis direction needs to be kept within a certain range, which is a fact having been proved through experiments conducted by the inventors.

A state in which the step edges are regularly arranged in the m-axis direction is a necessary condition for the formation of a flat film. If the intervals for the step edges or the step-edge lines are formed in a disorderly fashion, the above-described lateral growth becomes impossible. Consequently, no flat film can be formed.

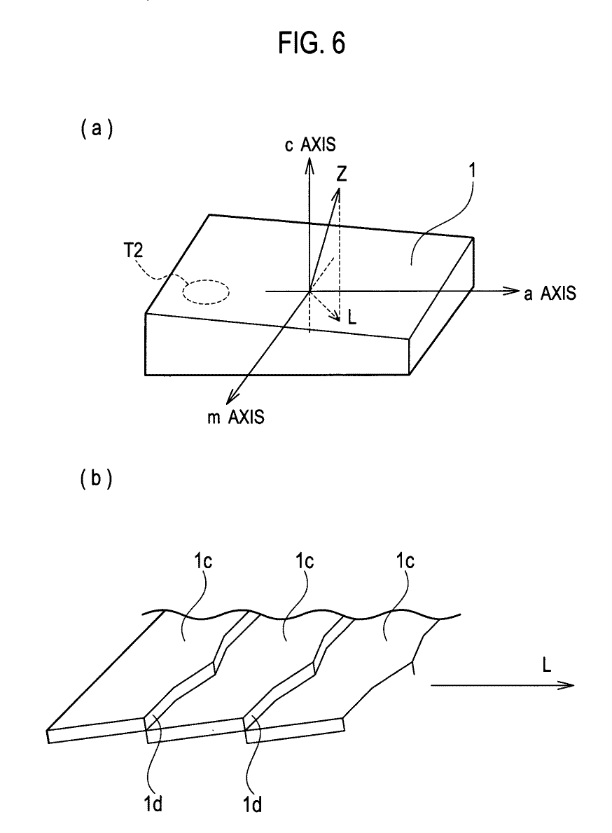

If the normal line Z to the principal surface tilts both towards the m-axis and towards the a-axis as in the case shown in FIG. 4, the principal surface can be expressed in a manner shown in FIG. 6(a). The coordinate axes and the like of the diagram of FIG. 6(a) are set in a similar manner to that of FIG. 5. The direction L shown in FIG. 6 is the direction of a projection axis obtained by projecting the normal line Z to the substrate's principal surface onto the a-axis/m-axis plane in the Cartesian coordinate system defined by the c-axis, the m-axis, and the a-axis, which are the substrate's crystal axes. FIG. 6(b) is an enlarged diagram illustrating a portion (for example, an area T2) of the surface of the substrate 1. Flat faces (terrace faces 1c) and step faces 1d are formed. Each step face 1d appears at a portion where a difference in level is formed due to the fact that the normal line Z tilts. Here, the terrace faces serves as the C-plane (0001), but the case shown in FIG. 6(b) differs from the case shown in FIG. 5 in terms of the fact that the normal line Z tilts, by an angle Φ, from the c-axis that is perpendicular to the terrace planes as shown in FIG. 6(a).

Since the normal line direction to the substrate's principal surface tilts not only towards the m-axis but also towards the a-axis, the step faces are formed obliquely so that the step faces are arranged in the L-direction. This state brings about a step-edge arrangement in the L-direction shown in FIG. 4. However, since the M-plane is a plane that is stable both thermally and chemically, a certain tilting angle Φₐ in the a-axis direction prevents the oblique steps from being formed neatly. Consequently, asperities are formed on the step faces 1d, and the step-edge arrangement becomes in disorder. As a result, no flat film can be formed on the principal surface, resulting in a state shown FIG. 6(b).

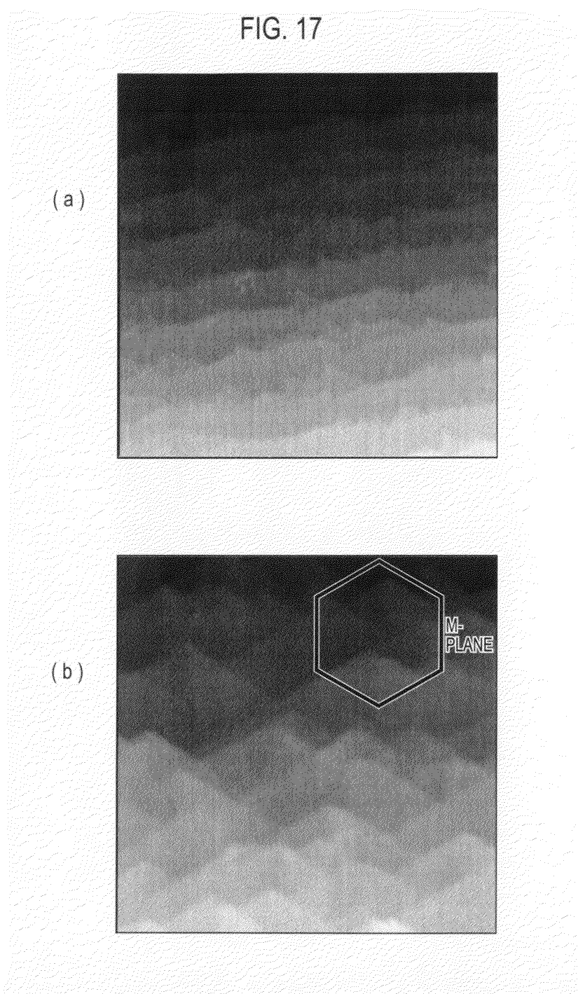

The fact that the M-plane is stable both thermally and chemically was discovered by the inventors. FIGS. 16 to 19 show the data that testify the discovery of the inventors. FIG. 16 shows an image obtained by scanning the surface of a MgₓZn₁₋ₓO substrate by use of an AFM with a view field of a 5-μm square. Each of the images shown in FIGS. 17 to 19 is obtained by scanning with a view field of a 1-μm square. Here, a ZnO substrate is used as the MgₓZn₁₋ₓO substrate.

FIG. 16(a) shows the state after an exposed A-plane of the MgₓZn₁₋ₓO substrate is subjected to an annealing process at 1100° C. in the atmosphere for two hours. FIG. 16(b) shows the state after an exposed M-plane of the MgₓZn₁₋ₓO substrate is subjected to an annealing process at 1100° C. in the atmosphere for two hours. FIG. 16(b) shows a neat surface while FIG. 16(a) shows a bad surface state in which step bunching appears and both the widths and edges of the steps are in disorder. On the basis of this observation, the M-plane can be considered as a thermally stable plane.

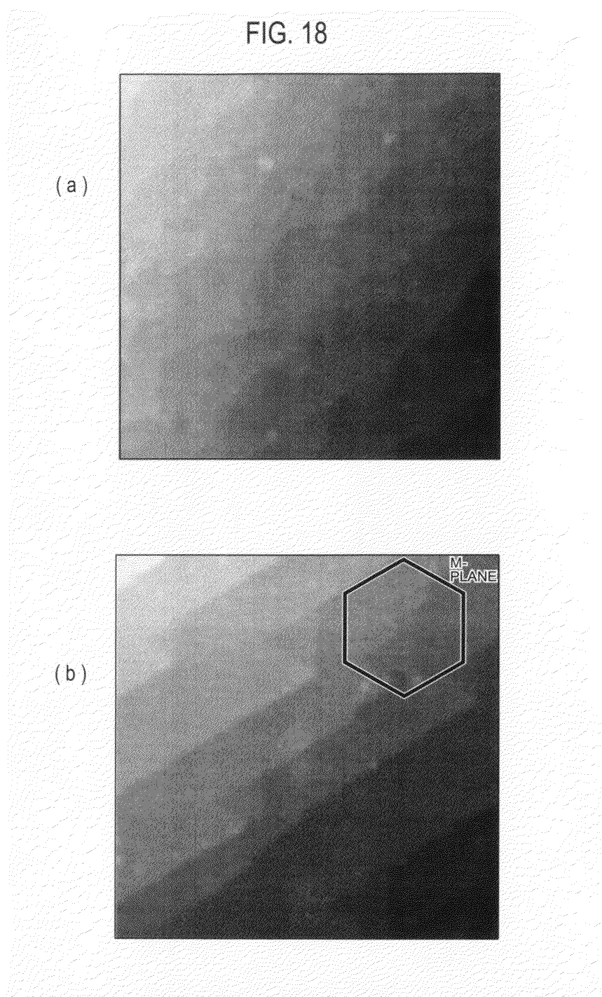

In the meantime, FIG. 17(a) shows a surface state of a case where the c-axis of the principal surface of the MgₓZn₁₋ₓO substrate tilts both towards the a-axis and towards the m-axis. In the surface state shown in FIG. 17(a), the M-plane does not appear in a neat manner as in the case of FIG. 6(b). FIG. 17(b) shows a state of the surface after a 30-second etching process with a 5% hydrochloric acid. The etching with the hydrochloric acid removes the planes other than the M-plane as shown by the hexagonal area in FIG. 17(b), so that the M-plane appears in a noticeable fashion. Further, FIG. 18(a) shows the surface of another MgₓZn₁₋ₓO substrate with the tilting angle towards the a-axis being different from the one in the case shown in FIG. 17(a). FIG. 18(b) shows a state of the surface after a 30-second etching process with a 5% hydrochloric acid. As the hexagonal area of FIG. 13(b) shows, the planes other than the M-plane are removed, so that the M-plane appears in a noticeable fashion.

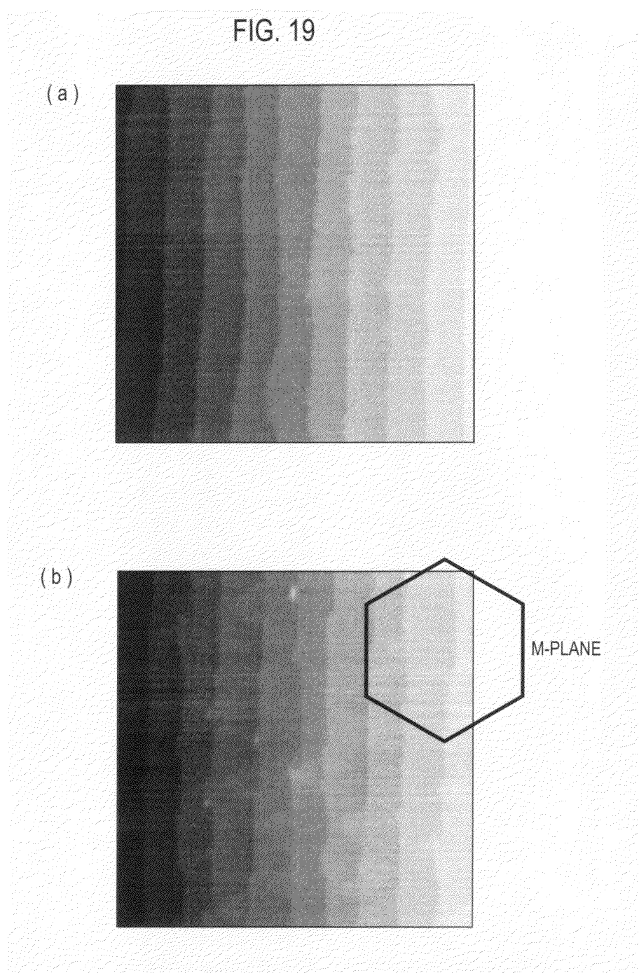

Meanwhile, FIG. 19(a) shows a surface state of a case where the normal line Z to the principal surface of the MgₓZn₁₋ₓO substrate tilts only towards the m-axis. The surface state shown in FIG. 19(a) is like the one shown in FIGS. 5(b) and 5(c). In FIG. 19(a), it is shown that the step edges of the M-plane are arranged perpendicularly to the m-axis. FIG. 19(b) shows a state of the surface after a 30-second etching process with a 5% hydrochloric acid. FIG. 19(b) shows that few changes occur in the surface state even through the etching process. The data shown in FIGS. 17 to 19 testify the fact that the M-plane is a chemically stable plane.

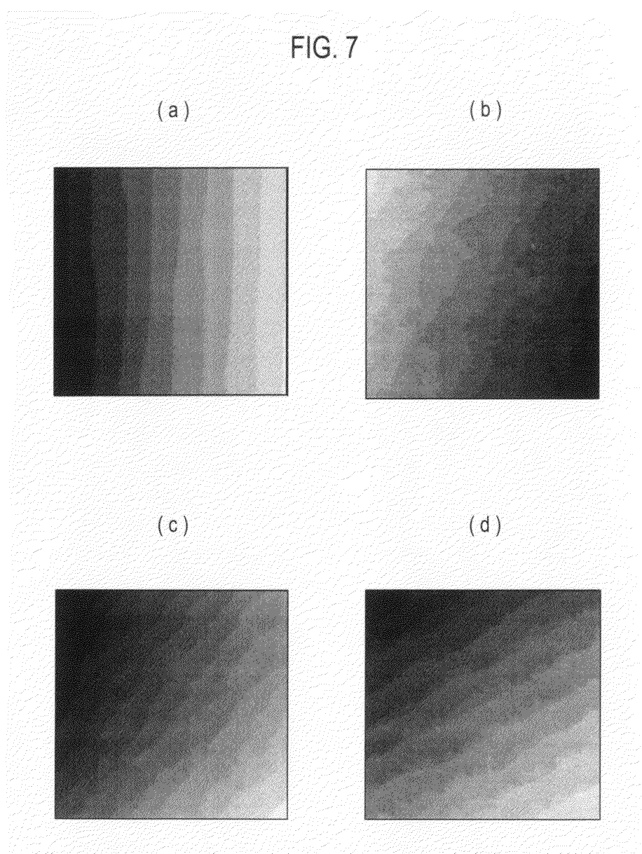

FIG. 7 shows the surfaces of MgₓZn₁₋ₓO substrates in each of which the normal line Z to the principal surface has a tilting angle (off-angle) from the c-axis towards at least the m-axis and has also a certain off-angle towards the a-axis, as described above. The image of the surface of each MgₓZn₁₋ₓO substrate is taken with an AFM. FIG. 7(a) shows the surface state of a case where the normal line Z to the principal surface tilts from the c-axis only towards the m-axis but not towards the a-axis. Each of FIGS. 7(b) to 7(d) shows the surface state of a case where the normal line Z to the principal surface tilts from the c-axis not only towards the m-axis but also towards the a-axis. The tilting angle towards the a-axis is gradually increased from the case shown in FIG. 7(b) to the case shown in FIG. 7(d).

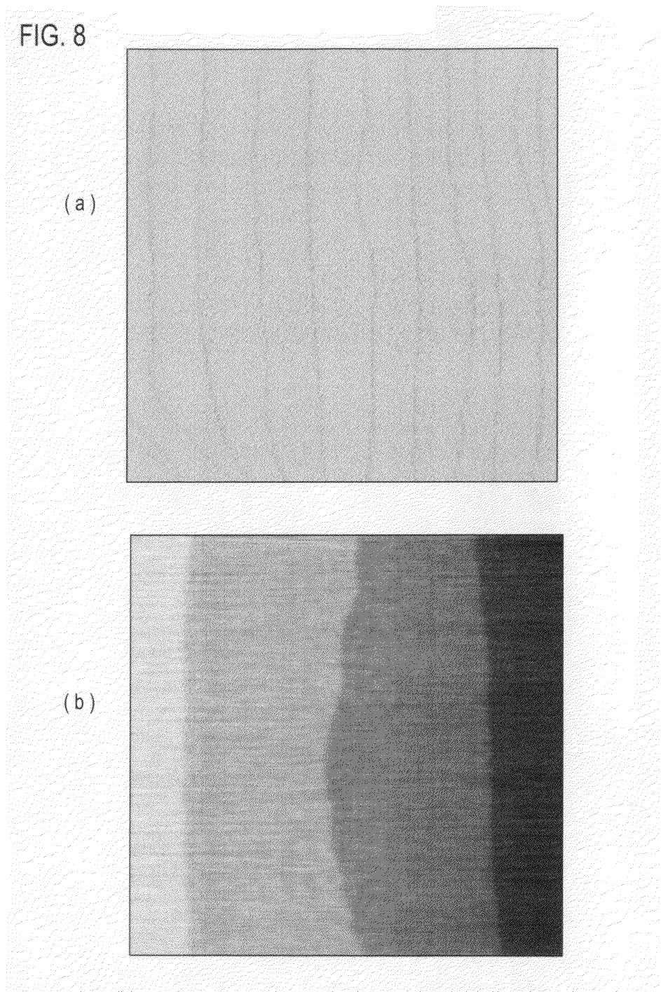

FIG. 7(a) shows the surface state of a case where the normal line Z tilts only towards the m-axis by 0.3 degrees. The surface state shown in FIG. 7(a) is very neat with the step edges arranged in a regular manner. FIG. 8 is of a case where a ZnO-based semiconductor layer is grown epitaxially on the MgₓZn₁₋ₓO substrate of FIG. 7(a). FIG. 8(a) shows an image obtained by scanning, with an AFM, a 3-μm square area of the surface after the epitaxial growth. FIG. 8(b) shows an image obtained by scanning a 1-μm square area. It is observed that the surface state is very neat with no scattering of asperities.

On the other hand, when there exists an off-angle towards the a-axis, asperities appear at step edges and the step widths become in disorder. Consequently, the formation of the film is adversely affected.

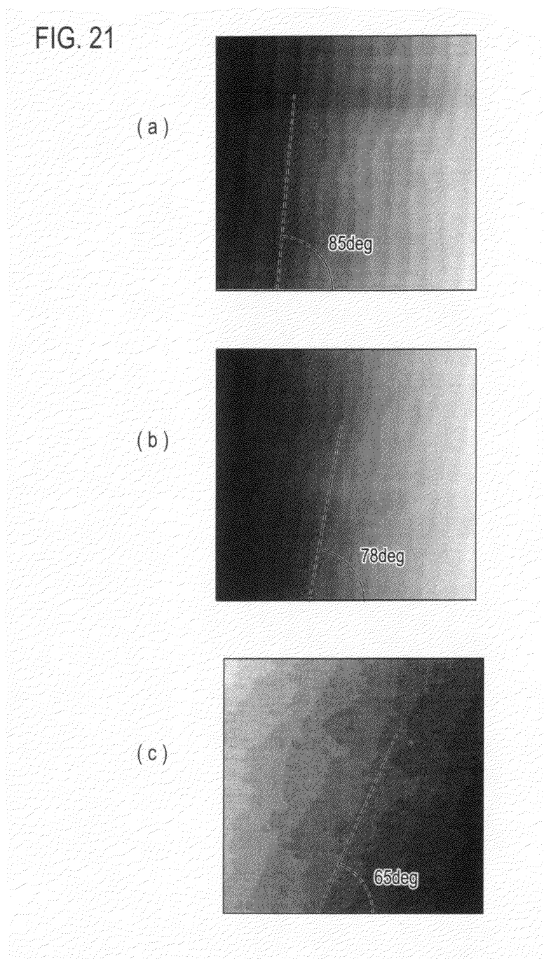

FIG. 21 shows how the states of the step edges and the widths of the steps change if the C-plane in the growth plane (principal surface) has not only an off-angle towards the m-axis but also an off-angle towards the a-axis. The off-angle Φₘ towards the m-axis, which was described earlier by referring to FIG. 4, was fixed to 0.4 degrees, and the off-angle Φₐ towards a-axis was changed so as to become larger to make a comparison. This was achieved by cutting out the MgₓZn₁₋ₓO substrates used in the comparison by different planes. When a different plane for the MgₓZn₁₋ₓO substrate is to be cut out, a cut with precision can be done by positioning the crystal boule with its directions set using an XRD (X-ray diffractometer).

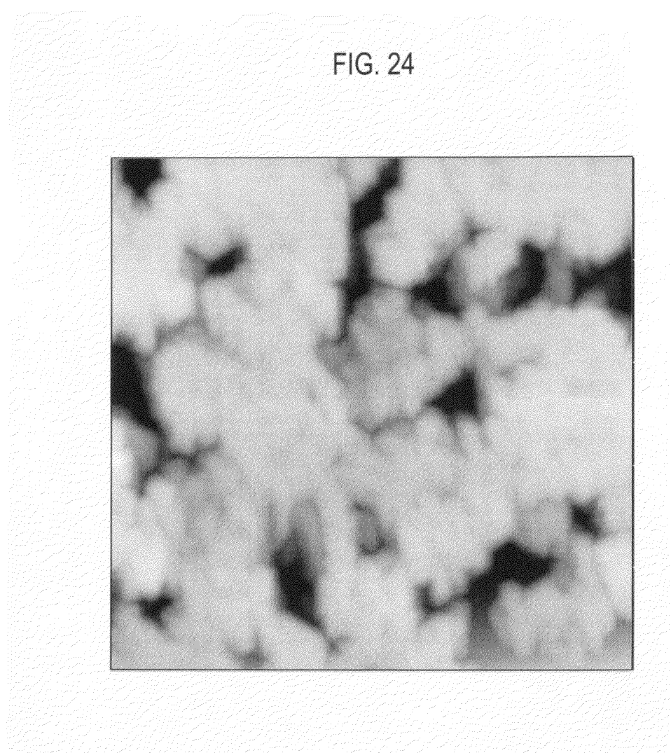

As the off-angle Φₐ towards a-axis is increased, the angle θₛ formed by each step edge with the m-axis direction is also increased. So the values of the angle θₛ are put in FIG. 16. FIG. 21(a) is of a case where the angle θₛ is 85 degrees. Neither the step edges nor the step widths are in disorder. FIG. 21(b) is of a case where the angle θₛ is 78 degrees. Although slight disorder can be observed, the step edges and the step widths are still recognizable. FIG. 21(c) is of a case where the angle θₛ is 65 degrees. The disorder worsens, so that neither the step edges nor the step widths are recognizable. If a ZnO-based semiconductor layer is grown epitaxially on a surface in the state shown in FIG. 21(c), a film that is formed is in the state shown in FIG. 24. If the angle θₛ of 65 degrees of the case of FIG. 21(c) is converted to the tilting angle Φₐ towards the a-axis, the tinting angle θₐ of this case is 0.15 degrees. The data having been described thus far show that the angle θₛ is preferably within a range of 70 degrees≦θₛ≦90 degrees.

Incidentally, the cases that have to be taken into consideration if a preferable range of the angle θₛ is pursued include not only the case where the normal line Z to the principal surface tilts in the a-axis direction by an angle θₐ but also the case where the normal line Z tilts in the −a-axis direction because the latter case is equivalent to the former case in terms of the symmetry. The case where the tilting angle in the −a-axis direction is denoted by −Φₐ and the level-difference portions formed by the step faces are projected onto the a-axis/m-axis plane can be shown as in FIG. 4(c). Here, regarding the condition for the angle θᵢ formed by each step edge and the m-axis, the above-described condition, 70 degrees≦θᵢ≦90 degrees, is satisfied. Since θₛ=180 degrees−θᵢ is satisfied, the maximum value of the angle θₛ is 180 degrees−70 degrees=110 degrees. Eventually, the range of 70 degrees≦θₛ≦110 degrees is the condition to be satisfied if a flat film is to be grown.

As has been described thus far, it was found that, if a flat film is to be formed, it is preferable that the tilting angle by which the c-axis of the growth plane of the MgₓZn₁₋ₓO substrate tilts towards the a-axis should satisfy the relationship of 70 degrees≦θₛ≦90 degrees. Subsequently, the unit for the angles is changed to radian (rad), and the angle θₛ will be expressed below using Φₘ and Φₐ on the basis of FIG. 4. Firstly, the angle α shown in FIG. 4 is expressed as:

α=arctan(tan Φₐ/tan Φₘ)

Accordingly,

θₛ=(π/2)−α=(π/2)−arctan(tan Φₐ/tan Φₘ)

Here, if the unit for the angle θₛ is converted from radian to degree,

θₛ=90−(180/π)arctan(tan Φₐ/tan Φₘ)

Thus,

70≦{90−(180/π)arctan(tan Φₐ/tan Φₘ)}≦110

Here, as is well known, “tan” and “arctan” are the abbreviations of tangent and arctangent, respectively. Note that a case where θₛ=90 degrees corresponds to the case with no tilting towards the a-axis but with the tilting only towards the m-axis. In addition, if the angles Φₘ and Φₐ are not in radian but in degree, the inequation given above can be expressed as

70≦{90−(180/π)arctan(tan(πΦₐ/180)/tan(πΦₘ/180))}≦110

Subsequently, a method of manufacturing a ZnO-based semiconductor device shown in FIG. 1 will be described below. In the method, the sloping surface on the laminate side of the MgₓZn₁₋ₓO substrate 1 is formed in the above-described way.

Firstly, the MgₓZn₁₋ₓO substrate 1 is cut out from a ZnO ingot manufactured by, for example, a hydrothermal synthesis method. The MgₓZn₁₋ₓO substrate 1 is cut out in such a way as that, as described above, the normal line to the principal surface tilts from the c-axis of the substrate's crystal axes at least towards the m-axis, and, if the normal line has an off-angle towards the a-axis, the off-angle is within a certain range. Specifically, if the angle Φₐ shown in FIG. 4 is to be larger than 0 degree but is not larger than 3 degrees and the normal line is to tilt toward the a-axis, the MgₓZn₁₋ₓO substrate 1 is cut out so that the angle θₛ shown in FIG. 4 is not smaller than 70 degrees but is not larger than 110 degrees. The MgₓZn₁₋ₓO substrate 1 thus cut out is then polished by the chemical mechanical polishing (CMP) method, and thus a wafer is obtained.

Note that, even if the Mg content mixed in the crystal of the substrate 1 is zero, the crystallinity of the ZnO-based semiconductor to be grown on the substrate 1 is hardly affected. However, if the material of the substrate 1 has a larger band gap than the wavelength of the light to be emitted (the composition of the activation layer), the light to be emitted would not be absorbed by the substrate 1. Thus, the mixing of Mg into the crystal is preferable.

Then, to grow the ZnO-based compound, an MBE apparatus equipped with a radical source capable of generating oxygen radicals by raising the reaction activity of oxygen gas with RF plasma. The same radical source as the one mentioned above is also used for the nitrogen, which is the p type dopant for the ZnO. The Zn source, the Mg source, and the Ga source (n type dopant) are provided as metals of Zn, Mg, and the like with a purity of 6N (99.9999%) or higher. These metals are supplied from Knudsen cells (evaporation source). A shroud in which liquid nitrogen flows is provided around the MBE chamber so as to prevent the wall surface from being heated up by the heat radiation from the cells and the heater for the substrate. In this way, the inside of the chamber can be kept at a high vacuum of approximately 1×10⁻⁹ Torr.

The ZnO wafer having been polished by the CMP method (substrate 1) is placed in the MBE apparatus with the above-described configuration. Then, the wafer is thermally cleaned at a temperature ranging from 700° C. to 900° C., approximately. After the cleaning, the temperature of the substrate 1 is changed to approximately 800° C., and the ZnO-based semiconductor layers 2 to 5 are grown one after another.

Here, the p type ZnO-based semiconductor 5 is formed as a p type ZnO contact layer 5 with a film thickness within a range from 10 nm to 30 nm, approximately. The portions around the activation layer are formed to be a double hetero structure. Specifically, the activation layer 3 is sandwiched by the n type layer 2 and the p type layer 4 both of which are made of Mg_{y}Zn_{1-y}O (where 0≦y≦0.35; y=0.25 for example) with a larger band gap than that of the activation layer 3. For example, though not illustrated, the activation layer 3 is formed so as to have a multiquantum well (MQW) structure. The MQW structure is achieved by forming a laminate structure including, in the following order from the bottom to the top: an n type guide layer made of an n type Mg_{z}Zn_{1-z}O (where 0≦z≦0.35; z=0.2, for example) and having a thickness of approximately 0 to 15 nm; a laminate portion including Mg_{0.1}Zn_{0.9}O layers each having a thickness of approximately 6 to 15 nm and ZnO layers each having a thickness of approximately 1 to 3 nm, the Mg_{0.1}Zn_{0.9}O layers and the ZnO layers being formed alternately by 6 cycles; and a p type guide layer made of p type Mg_{0.1}Zn_{0.9}O and having a thickness of approximately 0 to 15 nm. The activation layer 3 is formed so as to emit light with a wavelength of, for example, approximately 365 nm. However, the above-described example is not the only possible structure of the activation layer. For example, the activation layer 3 may have a single quantum well (SQW) structure or a bulk structure. In addition, instead of the double heterojunction structure, the activation layer 3 may have a pn structure of single heterojunction. Moreover, each of the n type layer 2 and the p type layer 4 may have a laminate structure including a barrier layer and a contact layer. Furthermore, a gradient layer may be formed between the two layers forming a heterojunction. Still furthermore, a reflection layer may be formed on the substrate side.

Subsequently, the back-side surface of the substrate 1 is polished so that the thickness of the substrate 1 can be reduced down to approximately 100 μm. Then, layers of Ti and Al are formed on the back-side surface by the vapor-deposition method, the sputtering method, or the like. Then, the resultant substrate 1 is subjected to a sintering process at 600° C. for approximately 1 minute. Thus formed is the n electrode 9 with an ohmic property. Then, the p electrode 8 with a laminate structure of Ni and Au is formed on the surface of the p type contact layer 5 by the vapor-deposition method, the sputtering method, or the like. The wafer is then divided into chips by dicing or the like method. Thus formed is a chip of a light-emitting device with a structure shown in FIG. 1. Note that the n-side electrode 9 may be formed not on the back-side surface of the substrate 1 but on the surface of the n type layer 2 to be exposed by etching a part of a semiconductor laminate portion 7 including various layers. The above-described structures are only simple examples. The laminate structures are not the only possible examples.

The above-described example is of an LED. Also in the case of laser diode (LD), if the C-plane on the growth-plane side of the MgₓZn₁₋ₓO substrate used as the growth substrate tilts by an angle within the above-described range, a certain flatness of each of the ZnO-based semiconductor layers formed on the C-plane can be secured. Thus obtained is a semiconductor laser device with higher quantum effects.

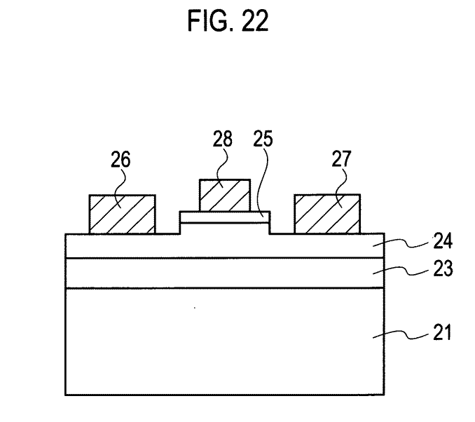

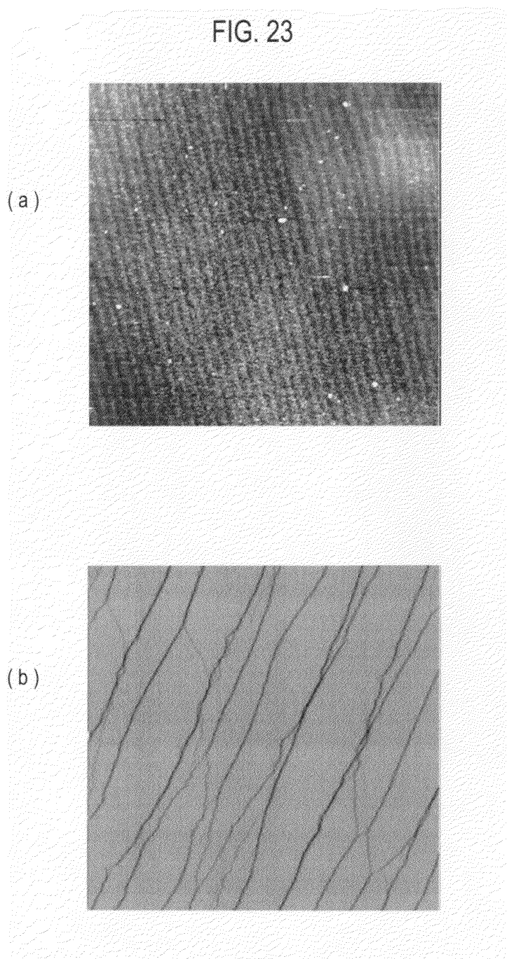

FIG. 22 shows a cross-sectional structure of a transistor formed in the following way. Firstly, in the case where, as describe earlier, the angle Φₘ shown in FIG. 4 is larger than 0 degree but is not larger than 3 degrees and the normal line tilts towards the a-axis, an ZnO substrate 21 is formed so that the angle θₛ shown in FIG. 4 can be not smaller than 70 degrees but not larger than 110 degrees. Then, ZnO-based semiconductor layers are grown on the principal surface of the ZnO substrate 21. In this example, a transistor is formed in the following way. An undoped ZnO layer 23, an n type MgZnO-based electron-transit layer 24, and an undoped MgZnO-based layer 25 are sequentially grown so as to have thicknesses of approximately 4 μm, approximately 10 nm, and approximately 5 nm, respectively. Then, the undoped MgZnO-based layer 25 is removed by etching so that only a portion with a width of approximately 1.5 μm, which is to be the gate length, can be left. Thus, the electron-transit layer 24 is exposed. Then, on the electron-transit layer 24 thus exposed by the etching, a source electrode 26 and a drain electrode 27 are formed with, for example, a Ti film and an Al film. Then, a gate electrode 28 is formed, on the surface of the undoped MgZnO-based layer 25, with a laminate including, for example, a Pt film and a Au film.

In the device with the structure described above, the flatness of the film is improved in each of the semiconductor layers formed on the ZnO substrate I. Accordingly, a transistor (HEMT) having a high switching speed can be obtained.

1. A ZnO-based semiconductor device comprising:
a MgₓZn₁₋ₓO substrate (0≦x<1) having a principal surface including a C-plane; and
a ZnO-based semiconductor layer formed on the principal surface,
wherein, in the MgₓZn₁₋ₓO substrate, a projection axis obtained by projecting a normal line to the principal surface onto a plane defined by an m-axis and a c-axis of substrate's crystal axes, forms an angle of Φₘ degrees with the c-axis, and
wherein the angle of Φₘ degrees satisfies a condition 0<φₘ≦3.

2. The ZnO-based semiconductor device according to claim 1 wherein the angle of φₘ degrees satisfies the condition 0.1≦φₘ≦1.5.

3. The ZnO-based semiconductor device according to claim 2, wherein the C-plane is a +C-plane.

4. The ZnO-based semiconductor device according to claim 3, wherein
a projection axis obtained by projecting the normal line to the principal surface onto a plane defined by an a-axis and the c-axis of the substrate's crystal axes forms an angle of φₐ degrees with the c-axis, and
the angle of φₐ degrees satisfies a condition
70≦{90−(180/π)arctan(tan(πφₐ/180)/tan(πφₘ/180))}≦110.

5. A ZnO-based semiconductor device comprising:
a MgₓZn₁₋ₓO substrate (0≦x<1) having a principal surface including a C-plane; and
a ZnO-based semiconductor layer formed on the principal surface,
wherein, in the MgₓZn₁₋ₓO substrate, a normal line to the principal surface tilts from a c-axis only towards an m-axis, a tilting angle of the normal line being larger than 0 degree and not larger than 3 degrees.

6. The ZnO-based semiconductor device according to claim 5, wherein the tilting angle is not smaller than 0.1 degrees and is not larger than 1.5 degrees.

7. The ZnO-based semiconductor device according to claim 1 wherein the C-plane is a +C-plane.

8. The ZnO-based semiconductor device according to claim 7, wherein
a projection axis obtained by projecting the normal line to the principal surface onto a plane defined by an a-axis and the c-axis of the substrate's crystal axes forms an angle of φₐ degrees with the c-axis, and
the angle of φₐ degrees satisfies a condition
70≦{90−(180/π)arctan(tan(πφₐ/180)/tan(πφₘ/180))}≦110.

9. A ZnO-based semiconductor device according to claim 1, wherein
a projection axis obtained by projecting the normal line to the principal surface onto a plane defined by an a-axis and the c-axis of the substrate's crystal axes forms an angle of φₐ degrees with the c-axis, and
the angle of φₐ degrees satisfies a condition
70≦{90−(180/π)arctan(tan(πφₐ/180)/tan(πφₘ/180))}≦110.
